(19) United States
(12) Patent Application Publication
(10) Pub. No.: US 2007/0216295 A1
(43) Pub. Date: Sep. 20, 2007

(54) Electroluminescent element and production method thereof

(75) Inventor: Takahisa Shimizu, Tokyo (JP)

Correspondence Address: SQUIRE, SANDERS & DEMPSEY L.L.P., 1 MARITIME PLAZA, SUITE 300, SAN FRANCISCO, CA, 94111, US

(73) Assignee: Toppan Printing Co., Ltd., Tokyo (JP)

(21) Appl. No.: 11/716,073

(22) Filed: Mar. 8, 2007

(30) Foreign Application Priority Data
Mar. 15, 2006 (JP) 2006-070458

(51) Int. Cl. H01L 51/54

(52) U.S. Cl. 313/506; 428/690; 428/917; 257/40; 257/E51.027; 427/66

(57) ABSTRACT

The invention is intended to provide an organic EL element provided with a film capable of preventing immigration of impurity even when a material such as dope type PEDOT/PSS of which impurity can immigrate to a light emitting layer is used and a production method therefore, the film of the organic EL element being excellent in uniformity and easily formed. In the organic EL element, a first electrode, an organic light emitting medium layer, and a second electrode are formed on a substrate; the organic light emitting medium layer at least includes a positive hole transport layer and an organic light emitting layer; and a second positive hole transport layer having positive hole mobility in the range of 1×10⁻⁴ to 1 cm²/v·s is formed between the positive hole transport layer and the organic light emitting layer.

### CROSS REFERENCE

This application claims priority to Japanese patent application number 2006-070458, filed on Mar. 15, 2006, which is incorporated by reference.

### BACKGROUND OF THE INVENTION

1. Field of the Invention

This invention relates to an organic thin film electroluminescent element utilizing electroluminescence phenomenon of an organic thin film and, particularly, to a polymer electroluminescent element having an organic light emitting layer made from an organic light emitting material.

2. Description of the Related Art

An electroluminescent element (hereinafter referred to as EL element) is a light emitting element which is provided at least with a substrate, a first electrode, a light emitting medium layer, and a second electrode, wherein the first electrode, the light emitting medium layer, and the second electrode are formed on the substrate in this order. In the EL element, an organic light emitting layer emits light when a voltage is applied between the first electrode and the second electrode, and a first electrode side or a second electrode side transmits light so that the light is drawn out thereof. The electroluminescent element wherein an organic material is used as a material for forming the light emitting medium layer is called an organic EL element.

An organic light emitting medium layer made from an organic material is typically formed of plural layers that are different in function. Typical example of such organic light emitting medium layer is the one in which: copper phthalocyanine is used for a positive hole injection layer; N,N′-di(1-naphthyl)-N,N′-diphenyl-1,1′-biphenyl-4,4′-diamine is used for a positive hole transport layer; and tris(8-quinolinol)aluminum is used for a light emitting layer. The substances (functional material) forming and functioning the organic light emitting medium layer exemplified above are low molecular compounds, and each layer has a thickness of about 1 to 100 nm and stacked by a vacuum vapor deposition method such as a resistive heating method. Therefore, a vacuum vapor deposition apparatus wherein plural vapor deposition furnaces are connected is required for producing the thin film organic electroluminescent element using the low molecular materials, and there have been drawbacks of low productivity, high production cost, and difficulty in increasing size.

Also, a polymer electroluminescent element using a high molecular material as the functional material forming the organic light emitting medium layer is known.

The polymer EL element using the high molecular material as the functional material contained in the organic light emitting medium layer has a structure that the organic light emitting medium layer is sandwiched between the first electrode and the second electrode, which is similar to that of the EL element containing the low molecule as the functional material. The organic light emitting medium layer is a single layer formed only of an organic (polymer) light emitting layer or a multilayer formed of an organic light emitting layer and a layer containing a functional material for supporting light emission of a light emitting layer. For example, the structure is such that a positive hole transport layer, an organic light emitting layer, and an electron transport layer are formed in this order from an anode.

As the polymer type light emitting layer, those obtainable by dissolving a low molecular fluorescent dye into a polymer such as polystyrene, polymethylmethacrylate, polyvinylcarbazole and polymer light emitters such as a polyphenylenevinylene (PPV) derivative and a polyalkylfluorene (PAF) derivative are usable. Since it is possible to form a film from these high molecular materials by a coating process or a printing process by dissolving the high polymer material into a solvent, the polymer materials have advantages of enabling film formation in the atmosphere and low installation cost as compared to the organic EL element using the low molecular materials.

For the organic EL element provided with such polymer type light emitting layer, the structure wherein a positive hole transport layer containing a doped polythiophene (hereinafter referred to as PEDOT/PSS) material as the functional material is provided at the anode side as the positive hole transport material is frequently used at present. However, a problem that light emission life of the light emitting layer is reduced due to contamination of the light emitting layer with impurity from the dopant has been raised.

In order to solve the above problem, a method of providing a fluorine derivative thin film of about 10 nm between the PEDOT/PSS layer and the light emitting layer has been proposed. It has been reported that the thus-provided thin film prevents leaching of the impurity from the PEDOT/PSS and is used as an electron blocking layer for blocking entrance of electrons from the anode side (Non-patent Publication 1).

However, since it is necessary to keep the thickness of the thin film made from the reported material to about 10 nm which is very thin, the formation method is limited. Therefore, though the thin film can barely be formed by the spin coating, there are problems that it is remarkably difficult to achieve uniformity in film thickness by various coating methods and a printing process capable of forming a pattern and that the element does not emit light uniformly when the film is not uniform.

Accordingly, this invention has been accomplished in order to provide an organic EL element provided with a film capable of preventing immigration of impurity even when a material such as dope type PEDOT/PSS of which impurity can immigrate to a light emitting layer is used and a production method therefore, the film of the organic EL element being excellent in uniformity and easily formed.

[Non-patent Publication 1] Applied Physics Letters, Vol. 80, PP 2436-2438

### SUMMARY OF THE INVENTION

It is intended to provide an organic EL element provided with a film capable of preventing immigration of impurity even when a material such as dope type PEDOT/PSS of which impurity can immigrate to a light emitting layer is used and a production method therefore, the film of the organic EL element being excellent in uniformity and easily formed. In the organic EL element, a first electrode, an organic light emitting medium layer, and a second electrode are formed on a substrate; the organic light emitting medium layer at least comprises a positive hole transport layer and an organic light emitting layer; and a second positive hole transport layer having positive hole mobility in the range of 1×10⁻⁴ to 1 cm²/v·s is formed between the positive hole transport layer and the organic light emitting layer.

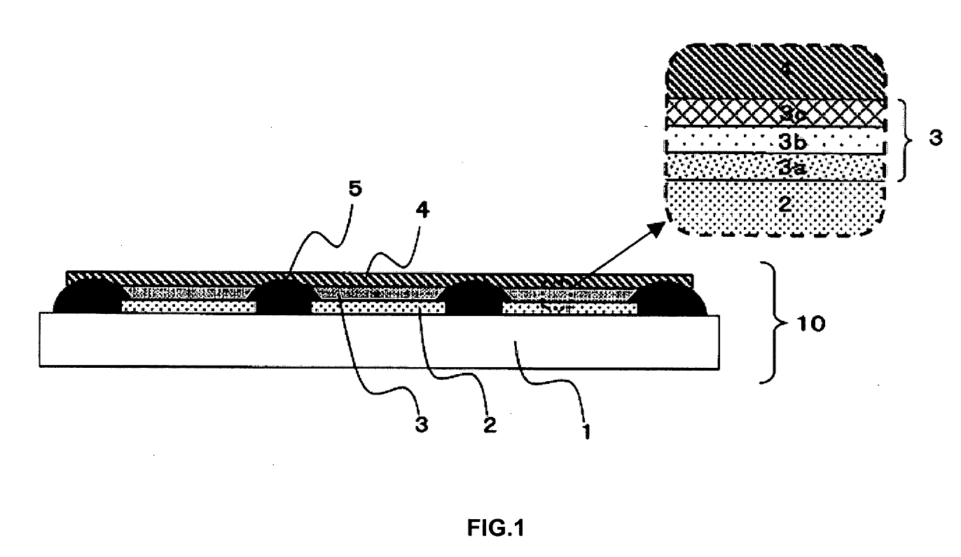

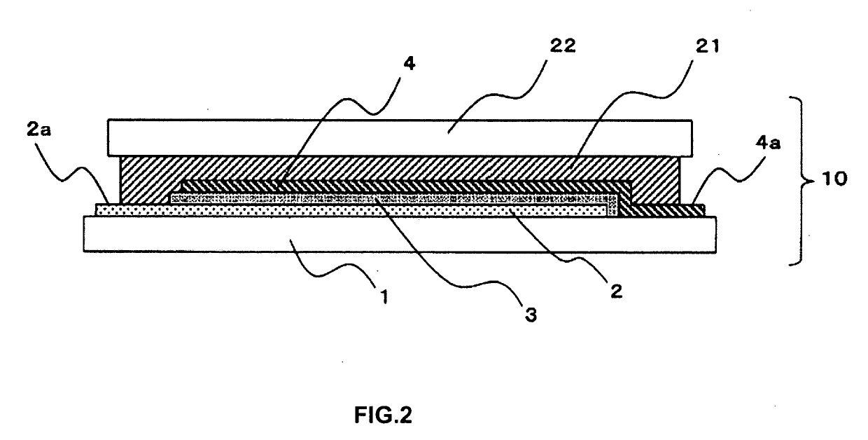

### BRIEF DESCRIPTION OF THE DRAWINGS

[FIG. 1] A schematic sectional view showing one example of an organic EL element of this invention.

[FIG. 2] A schematic sectional view showing one example of the organic EL element which is sealed.

### DESCRIPTION OF REFERENCE NUMERALS

1: substrate

2: first electrode

2a: takeoff portion

3: organic light emitting medium layer

3a: positive hole transport layer

3b: second positive hole transport layer

3c: organic light emitting layer

4: second electrode

4a: takeoff portion

5: insulating partition

10: polymer EL element

21: adhesive agent

22: sealing substrate

### DESCRIPTION OF THE PREFERRED EMBODIMENTS

Hereinafter, details of an organic EL element according to this invention will be described based on FIG. 1.

The organic EL element of this invention is provided at least with a substrate, a first electrode, an organic light emitting medium layer, and a second electrode, wherein the first electrode, the organic light emitting medium layer, and the second electrode are formed on the substrate. The organic light emitting medium layer is provided at least with a positive hole transport layer and an organic light emitting layer, and a second positive hole transport layer having positive hole mobility in the range of 1×10⁻⁴ to 1 cm²/v·s is formed between the positive hole transport layer and the organic light emitting layer.

A substrate usable as the substrate 1 (FIG. 1) in this invention is not limited insofar as the substrate has strength capable of retaining the electrodes and the organic light emitting medium layer. More specifically, a glass substrate and a plastic film or sheet are usable. It is possible to produce a thin film organic EL element having remarkably high barrier properties by using a thin glass substrate of 0.2 to 1 mm.

In the case where a flexible plastic film is used, it is possible to produce organic EL elements successively by winding, thereby enabling to provide inexpensive elements. For the plastic film, polyethylenetelephthalate, polypropylene, a cycloolefin polymer, polyamide, polyethersulfone, polymethylmethacrylate, polycarbonate, and the like are usable. Also, when a ceramic vapor deposition film or a gas barrier film of polyvinylidene chloride, polyvinyl chloride, an ethylene-vinyl acetate copolymer saponified matter, or the like is formed on the part where the first electrode 2 is not formed, the barrier properties are further improved, thereby enabling to provide a long life organic EL element.

In view of the barrier properties for preventing permeation of water vapor and oxygen, a metal thin film and a metal thin plate are useful in addition to the glass substrate: however, it is necessary to subject the metal thin film and the metal thin plate to a treatment for achieving insulation between the metal thin film or plate and the first electrode. Further, it is necessary to select a light transmitting material for the first electrode 2 in the case of producing an organic EL element of a so-called bottom emission structure wherein light is drawn out from the first electrode part, and it is also necessary to select a light emitting material for the substrate 1 in such case.

The first electrode 2 is formed on the substrate 1 directly or indirectly via a flattening layer or the like. In the case where the first electrode functions as an anode, it is preferable to use a compound oxide of indium and tin (hereinafter referred to as ITO), for example. The first electrode is formed on the substrate 1 by vapor deposition or sputtering. It is also possible to form the first electrode by coating a precursor such as indium octylate and acetone indium on a base material and then performing a coating pyrolysis method for forming an oxide by thermal decomposition. Alternatively, it is possible to use those on which a metal such as aluminum, gold, silver, or the like is provided by vapor deposition in a translucent state. Further, an organic semiconductor such as polyaniline may be used. In the case of forming a polymer EL element of bottom emission type, an electroconductive substance capable of forming a transparent or translucent electrode is selected.

The first electrode 2 may be patterned by etching or subjected to surface activation by a UV treatment, a plasma treatment, or the like when so required.

In the case of producing the organic EL element as a display capable of matrix display, the first electrodes are formed in the form of stripes, and the second electrodes which are to be formed in such a fashion that the organic light emitting layer is sandwiched between the first electrode and the second electrode are formed in the form of stripes that intersect the first electrodes at right angle, so that a passive matrix display wherein light is emitted from the intersections is realized. Also, it is possible to form thin film transistors corresponding to respective pixels on the substrate 1 and to form the first electrodes corresponding to the respective pixels in such a fashion as to be electrically connected to the thin film transistors.

In the case of patterning the first electrodes by etching, irregularity in an edge portion of the first electrode pattern can sometimes be too large to be covered by the organic light emitting medium layer which is to be formed above the first electrodes. In such cases, the first electrode and the second electrode can undesirably be shorted out. Therefore, it is preferable to coat the edge portion of the first electrodes with an insulating resin or the like. For the coating of the first electrode edge portion, photosensitivity is imparted to a composition of a resin such as polyimide, acryl, and polyurethane, and then the photosensitive rein composition is applied, subjected to mask light exposure, and development.

By keeping a height of the insulating resin (insulating partition 5) covering the edge portion of the first electrodes to a value larger than a certain value, for example from 0.5 to 1.5 μm, the insulating partition 5 functions to prevent color mixing of adjacent pixels in the case where the organic light emitting medium layer to be formed on one of the first electrode pattern is different from that formed on the adjacent first electrode pattern, e.g. when colors of light emitted from the light emitting layers are different from each other.

The organic light emitting medium layer 3 of the organic EL element in this invention is provided at least with the positive hole transport layer 3a and the organic light emitting layer 3c, and the second positive hole transport layer 3b having positive hole mobility of 1×10⁻⁴ to 1 cm²/v·s is formed between the positive hole transport layer and the organic light emitting layer (FIG. 1).

As a positive hole transport material to be used for the positive hole transport layer 3a, a dope type positive hole transport material may preferably be used. The dope type positive hole transport material is an electroconductive polymer which contains a small amount of an electron acceptor material to achieve the electroconductivity and is capable of transmitting the positive hole (hole) to the organic light emitting layer. Examples of the dope type positive hole transport material include dope type polythiophene and the like. Particularly, an organic material obtained by doping poly(3,4-ethylenedioxythiophene) with polystyrene sulfonic acid is suitably used since it is possible to form a film from the organic material by a wet process.

The functional material to be used for the positive hole transport layer 3a is processed into an ink form by dissolution or dispersion thereof into a solvent, and the ink form functional material is stacked by a method such as a coating process, a printing process, and a liquid droplet discharge process on the substrate on which the first electrode has been formed. As the solvent for dissolving or dispersing the positive hole transport material, water or an alcohol-based solvent may preferably be used in view of solubility of a light emitting material to be contained in the adjacent organic light emitting layer.

General examples of the coating process include spin coating, dipping, bar coating, slit coating (die coating), and the like.

Examples of the printing process include various printing methods such as a relief process, intaglio plate printing, flat plate printing, offset printing, and screen printing. Particularly, the relief process and the offset printing are preferred since it is possible to select a printing plate that contacts the print substrate or it is possible to select a resin or an elastic material as a blanket.

Also, as a method of disposing the ink without using a printing plate, an inkjet method can be employed.

The second positive hole transport layer 3b has a function of preventing transition of impurity and immigration of electrons from the positive hole transport layer to the organic light emitting layer. Examples of the impurity include an ionic substance such as a metal ion. Examples of a functional material usable for the second positive hole transport layer include the functional material used for the positive hole transport layer, which is a polymer or an oligomer not doped with a dopant. Further, it is preferable to select a material exhibiting high positive hole mobility in an undoped state, and the positive hole mobility may specifically be about 1×10⁻⁴ to 1 cm²/v·s, more preferably 1×10⁻² to 1 cm²/v·s. Examples of the functional material having such positive hole mobility include stereoregular polyalkylthiophene such as stereoregular poly(3-alkylthiophene) (0.1 cm²/v·s) and a polymer (1×10⁻² to 1 cm²/v·s) or an oligomer having a triphenylamine unit having high positive hole transport properties, such as crystalline polyalkylfluorene (4×10⁻³ to 1 cm²/v·s) and a triphenylamine starburst polymer (3×10⁻² to 1 cm²/v·s). Note that the functional material may preferably have a low solubility of about 1 wt % to toluene, xylene, and the like in view of the film formation method of the organic light emitting material to be stacked subsequently.

The positive hole mobility used as a criterion in this invention is measured by the Time-Of-Flight (TOF) method. The measurement conditions are as follows.

Measurement element structure: translucent A1 (20 nm)/material: 5 μm/A1 (80 nm)

### Excitation by a carbon gas laser

### Measurement at 130 V and 25° C.

An order of formation of the second positive hole transport layer is not limited insofar as the second positive hole transport layer is formed between the positive hole transport layer and the organic light emitting layer, and layers containing other functional materials (e.g. a positive hole injection layer and an insulating layer having positive hole mobility of less than 1×10⁻⁴ cm²/v·s) may be formed adjacent to the second positive hole transport layer.

Since the second positive hole transport material forming the second positive hole transport layer is the polymer or oligomer, it is possible to process the second positive hole transport layer into an ink form by dissolution or dispersion thereof into an appropriate solvent as well as to stack the ink form second positive hole transport material on the positive hole transport layer by a printing process or a coating method like the positive hole transport layer. As the solvent usable for adjusting the second positive hole transport material into the ink, the water-based or alcohol-based solvent used for adjusting the positive hole transport material into the ink form may preferably be used.

The second positive hole transport layer exhibits a favorable function when a thickness thereof is in the range of 10 to 30 nm. Since the positive hole mobility is 1×10⁻⁴ to 1 cm²/v·s, the thickness of 10 nm or more does not prevent the positive hole immigration. Also, since it is possible to form the second positive hole transport layer having the relatively large thickness of 10 nm or more, a film thickness change range allowable for the uniform light emission is wide, and it is possible to employ wet coating methods such as spin coating and printing processes. The thickness of 30 nm or less enables sufficient brightness without consuming an excessive amount of current.

The second positive hole transport layer not only prevents the impurity transition but also prevents electron immigration to the organic light emitting layer (electron blocking).

The organic light emitting layer 3c is formed on the second positive hole transport layer 3b which is formed on the positive hole transport layer 3a. For the organic light emitting layer, those obtainable by dispersing a low molecular light emitting material into a high molecular light emitting material or a polymer binder and high polymer light emitting materials are usable. For example, those obtainable by dissolving a light emitting dye such as coumarin-based, perylene-based, pyrane-based, anthrone-based, porphyrene-based, quinacridone-based, N,N′-dialkyl-substituted quinacridone-based, naphthalimide-based, and N,N′-diaryl-substituted pyrrolopyrrole-based dyes into a polymer binder such as polystyrene, polymethylmethacrylate, and polyvinylcarbazole that are generally used as an organic light emitting material may be used as the low molecular material, and polyparaphenylenevinylene-based (PPV-based), polyalkylfluorene-based (PAF-based), and polyparaphenylene-based materials may be used as the high molecular light emitting material.

Since the functional material forming the organic light emitting layer contains the polymer, it is possible to process the functional material into an ink form by dissolution or dispersion thereof into a solvent and to stack the ink form functional material on the second positive hole transport layer by a printing process or a coating method like the positive hole transport layer and the second positive hole transport layer. Though examples of the solvent to be used for adjusting the organic light emitting material into the ink include water-based and alcohol-based organic solvents, an aromatic organic solvent may preferably be used since the light emitting materials in general are subject to deterioration when exposed to moisture and hardly dissolved unless an organic solvent having a high solubility parameter is not used. Examples of such organic solvent include toluene, xylene, anisole, and the like.

The functional material (functional ink) adjusted into the ink form is coated on a whole surface in a uniform thickness by, for example, spin coating to obtain a functional ink coating, and then a functional thin film is obtained by eliminating the solvent. Particularly, in the case where it is necessary to select the organic light emitting materials different in light emission color for adjacent pixels, a method capable of coloring each of the pixels is preferred in view of prevention of color mixing of the adjacent pixels. Examples of such method include an ink jet method and a printing process. Particularly, the printing process is preferred since it is free from the color mixing even when a height of the insulating partition is relatively small and does not require addition of an ink-repelling substance to the partition. Particularly, a relief process which enables formation of a patterned film without damaging the print substrate and uses a resin relief plate as a printing plate is preferred.

As a method of drying the solvent contained in the ink, it is possible to select a method of leaving the ink in a heating state or a low pressure state insofar as the method enables elimination of the solvent without deteriorating the light emitting properties. Though it is possible to apply heat for the formation of the positive hole transport layer and the second positive hole transport layer, it is preferable to eliminate the solvent in the low pressure state in view of the influence on the light emitting properties since the light emitting material is more delicate.

A positive hole injection layer, an electron blocking layer, an electron transport layer, an electron injection layer, a positive hole blocking layer, an insulating layer, and the like may be provided in addition to the positive hole transport layer, the second positive hole transport layer, and the organic light emitting medium layer described above.

The second electrode 4 is formed above the organic light emitting medium layer 3 so that the organic light emitting medium layer 3 is sandwiched between the first electrode 2 and the second electrode 4. A positive hole and an electron are supplied to the organic light emitting medium layer 3 sandwiched between the first electrode 2 and the second electrode 4 when a current flows to the organic light emitting medium layer 3, and light is emitted by a bonding between the positive hole and the electron. In the case where the second electrode 4 is used as a cathode, a single metal such as Mg, Al, and Yb is used therefore. Also, a compound such as Li and LiF is inserted into a boundary contacting the organic light emitting layer by about 1 nm, and then Al or Cu which is high in stability and electroconductivity is stacked thereon. Alternatively, in order to keep both of electron injection efficiency and stability, an alloy of a metal having a low work coefficient and a stable metal, such as MgAg, AlLi, and CuLi, may be used. As a second electrode formation method, resistive heating vapor deposition, an electron beam process, or sputtering may be employed depending on the material of the second electrode. A thickness of the second electrode may preferably be 10 to 100 nm. In the case of using a so-called top emission structure wherein light is drawn from the second electrode part, it is necessary to select the material that realizes light transmitting properties of the second electrode 4 and a sealing layer described later in this specification.

It is possible to obtain the organic EL element of this invention as described in the foregoing.

Light emitting properties of the organic light emitting layer is deteriorated when the organic light emitting layer is exposed to moisture and oxygen. Also, since the metal used for the electrodes is high in reactivity since it contains the metal of family I or II, the metal reacts with water and oxygen. Therefore, a sealing base material such as a metal and a glass is attached in such a fashion as to cover the first electrode, the organic light emitting medium layer, and the second electrode for the purpose of keeping out external water and oxygen. A plastic film of PET or the like on which a film of silicon oxide or the like is deposited by vapor deposition may be used as the sealing base material in addition to the glass and the metal capable of preventing permeation of water and oxygen. The sealing base material is also effective for protecting the organic EL element from external physical pressure.

Shown in FIG. 2 is a schematic sectional view of the organic EL element which is obtained by forming the first electrode 2, the organic light emitting medium layer 3, and the second electrode 4 on the substrate 1 in this order and then sealing with the sealing base material 22 in the form of a plate by using an adhesive agent 21. In FIG. 2, reference numerals 2a and 4a denote takeoff portions of the first electrode and the second electrode.

A thin film of a nitride or a silicide, which is capable of preventing the permeation of moisture and oxygen, may be stacked on the second electrode by vapor deposition or the like before attaching the sealing base material. Also, in order to prevent dispersion of permeated moisture and oxygen, an oxygen absorbing agent or a water absorbing agent may be enclosed before sealing.

For stacking, a thermocurable adhesive and a photocurable adhesive may be used, but a photocurable adhesive is preferred since excessive heating causes an adverse influence on the light emitting properties of the EL element.

Since the organic EL element of this invention is provided with the second positive hole transport layer which is formed between the positive hole transport layer and the organic light emitting layer and has the positive hole mobility of 1×10⁻⁴ to 1 cm²/v·s, it is possible to enhance the light emission efficiency through the prevention of deterioration of the organic light emitting layer otherwise caused by the impurity immigration and through the electron blocking. Also, since it is possible to form the thick film as the second positive hole transport layer in the organic EL element of this invention, it is possible to achieve high film thickness uniformity of the second positive hole transport layer, thereby increasing production efficiency of the organic EL element having the excellent structure of uniformly emitting light while maintaining brightness. Particularly, even when the doped positive hole transport material is used for the positive hole transport layer, it is possible to prevent the ionic impurity immigration, thereby largely enhancing the element life. Further, since the range of selection of film formation methods for the immigration prevention layer is widened in addition to spin coating, it is possible to improve the material use efficiency. Also, it is possible to cope with production of large size substrates. Further, since the second positive hole transport layer has the high positive hole immigration ability and electron blocking ability, it is possible to enhance the light emission efficiency.

Furthermore, since it is possible to form all the functional thin films constituting the organic light emitting medium layer by the wet process such as coating and printing, it is possible to greatly improve the production efficiency of organic EL elements.

### EXAMPLE 1

As shown in FIG. 1, a glass substrate of 100 mm square was used as the transparent substrate 1, and ITO lines were provided at a pitch of 800 μm (L/S=700/100) as the transparent first electrodes 2. After that, an insulating resist was patterned by photolithography in such a fashion as to cover the ITO end portions to provide insulating partitions 5. After conducting UV/O₃ cleaning, a positive hole transport material ink which is a 1 wt % water dispersion solution of poly(3,4-ethylenedioxythiophene) and polystyrene sulfonic acid (hereinafter referred to as PEDOT/PSS) represented by the following chemical formula (1) was applied by slit coating in a thickness of 80 nm to form the positive hole transport layer 3a containing the dope positive hole transport material. In this example, the host was PEDOT, and the dopant was PSS. Further, by using a 0.5 wt % dichloroethane solution of stereoregular poly(3-alkylthiophene) (product of Aldrich; 0.1 cm²/v·s) as the undoped positive hole transport material, a film was formed by slit coating to obtain the second positive hole transport layer 3b. A thickness of the polyalkylthiophene thin film which was used as the second positive hole transport layer 3b was 25 nm. Uniformity of the film thickness of the polyalkylthiophene thin film was ±2 nm.

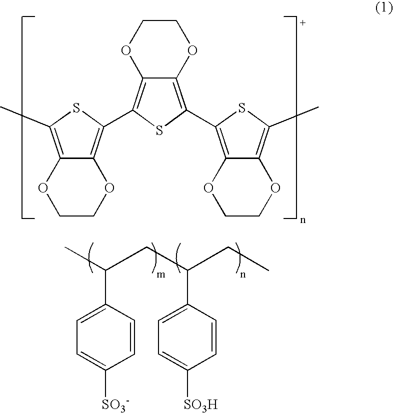

Then, 1.3 wt % of a polyfluorene-based high molecular light emitting material was dissolved into a solvent such as anisole to prepare an organic light emitting ink, and the organic light emitting ink was used for patterning on the previously formed second positive hole transport layer 3b to provide the organic light emitting layer 3c. The organic light emitting layer 3c was patterned by a resin relief process and had a film thickness of 50 nm.

Then, the second electrodes 4 having a thickness of 200 nm were formed by applying MgAg in the form of stripes of 800 μm pitch (L/S=700/100) by two-dimensional vapor deposition. In this example, the pattern of the second electrodes was disposed in such a fashion as to intersect with the pattern of the first electrodes at right angle. Thus, a passive driving type organic EL element of this invention was produced. Further, a photocurable adhesive agent was applied on a whole surface of a glass plate which was used as a sealing substrate, and then the sealing substrate was adhered to a second electrode formation surface of the organic EL element for sealing. The organic EL element was driven by direct driving with a start brightness of 400 Cd/m² (voltage: 5.2 V) by using the first electrodes as anodes and the second electrodes as cathodes, and a brightness halving time was 3,000 hours.

### EXAMPLE 2

An organic EL element was prepared by forming a thin film of a thickness of 20 nm (uniformity: ±2 nm) in the same manner as in Examples 1 except for using polydioctylfluorene (1×10⁻³ cm²/v·s) represented by the following chemical formula (2) which is crystalline polyalkylfluorene as an undoped positive hole transport material for forming the second positive hole transport layer 3b and sealed in the same manner as in Example 1. This organic EL element was directly driven in the same manner as in Example 1 with a start brightness of 400 Cd/m² (voltage: 8 V), and a brightness halving time was 1,500 hours.

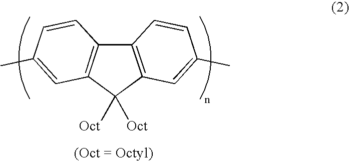

### COMPARATIVE EXAMPLE 1

An organic EL element was prepared by forming a polyalkylthiophene thin film of a thickness of 25 nm (uniformity: ±2 nm) in the same manner as in Examples 1 except for using polyalkylthiophene (product of Aldrich; 4×10⁻⁵ cm²/v·s) having small stereoregularity as an undoped positive hole transport material for forming the second positive hole transport layer 3b and sealed in the same manner as in Example 1. This organic EL element was subjected to direct driving in the same manner as in Example 1 with a start brightness of 400 Cd/m², but the brightness did not reach 400 Cd/m² even when the driving voltage was raised to 15 V.

### COMPARATIVE EXAMPLE 2

An organic EL element was prepared by forming a thin film of a thickness of 20 nm (uniformity: ±2 nm) in the same manner as in Examples 1 except for using a fluorine derivative (1×10⁻⁵ cm²/v·s) disclosed in Non-patent Publication 1 as an undoped positive hole transport material for forming the second positive hole transport layer 3b and sealed in the same manner as in Example 1. This organic EL element was directly driven in the same manner as in Example 1 with a start brightness of 400 Cd/m² (voltage: 12 V), and a brightness halving time was 50 hours. The brightness halving time was considerably short since it was necessary to apply the high voltage for increasing the brightness.

### COMPARATIVE EXAMPLE 3

An organic EL element was prepared in the same manner as in Examples 1 except for forming the organic light emitting layer 3c on the positive hole transport layer 3a without forming the second positive hole transport layer 3b and sealed in the same manner as in Example 1. This organic EL element was directly driven in the same manner as in Example 1 with a start brightness of 400 Cd/m² (voltage: 4.6 V), and a brightness halving time was 400 hours. The brightness halving time was short since the organic light emitting layer was deteriorated by ionic impurity.

### EXAMPLE 3

An organic EL element was prepared by forming a thin film of a thickness of 20 nm (uniformity: ±2 nm) as the second positive hole transport layer in the same manner as in Examples 1 and sealed in the same manner as in Example 1. The second positive hole transport layer was formed by printing employing a relief process using a resin relief plate corresponding to the shape of the first electrodes in place of the slit coating. This organic EL element was directly driven in the same manner as in Example 1 with a start brightness of 400 Cd/m² (voltage: 5.1 V), and a brightness halving time was 3,000 hours.

What is claimed is:

1. An organic electroluminescent element comprising:
a substrate;
a first electrode;
an organic light emitting medium layer, wherein the organic light emitting medium layer comprises a positive hole transport layer, an organic light emitting layer and a second positive hole transport layer having positive hole mobility in the range of 1×10⁻⁴ to 1 cm²/v·s formed between the positive hole transport layer and the organic light emitting layer; and
a second electrode.

2. The organic electroluminescent element according to claim 1, wherein the second positive hole transport layer has a film thickness of 10 to 30 nm.

3. The organic electroluminescent element according to claim 1, wherein the second positive hole transport layer contains an undoped positive hole transport material, and the positive hole transport material contained in the second positive hole transport layer and the positive hole transport layer is a polymer or an oligomer.

4. The organic electroluminescent element according to claim 3, wherein the undoped positive hole transport material is stereoregular poly(3-alkylthiophene).

5. The organic electroluminescent element according to claim 3, wherein the undoped positive hole transport material is crystalline polyalkylfluorene.

6. The organic electroluminescent element according to claim 3, wherein the undoped positive hole transport material is a polymer having a triphenylamine unit in its structure.

7. The organic electroluminescent element according to claim 3, wherein the undoped positive hole transport material is a triphenylamine starburst polymer.

8. A method for producing an organic electroluminescent element, wherein a first electrode, an organic light emitting medium layer, and a second electrode are formed on a substrate; the organic light emitting medium layer comprises a positive hole transport layer and an organic light emitting layer; and a second positive hole transport layer having positive hole mobility in the range of 1×10⁻⁴ to 1 cm²/v·s is formed between the positive hole transport layer and the organic light emitting layer, the method comprising:
forming the first electrode on the substrate;
forming the positive hole transport layer above the first electrode by a wet process;
for forming the second positive hole transport layer above the positive hole transport layer by a wet process;
forming the organic light emitting layer on the second positive hole transport layer by a wet process; and
forming the second electrode above the organic light emitting medium layer including the positive hole transport layer, the second positive hole transport layer, and the organic light emitting layer.
